(19) United States
(12) Patent Application Publication
(10) Pub. No.: US 2025/0142793 A1
(43) Pub. Date: May 1, 2025

(54) HEAT DISSIPATION APPARATUS AND METHOD

(71) Applicant: PassiveLogic, Inc., Holladay, UT (US)

(72) Inventors: Troy Aaron Harvey, Brighton, UT (US); Alexa Kalandiak, Salt Lake City, UT (US)

(21) Appl. No.: 18/498,604

(22) Filed: Oct. 31, 2023

(51) Int. Cl. H05K 7/20; H05K 5/02

(52) U.S. Cl. CPC H05K 7/20963; H05K 5/0217; H05K 7/20418

(57) ABSTRACT

Various embodiments described herein relate to a digital controller and related method including one or more of the following: a processor; a memory; and a hollow housing configured to be mounted to a surface such that at least a portion of the housing is disposed within an interior cavity of the surface, wherein a rear surface of the housing is made of a heat-conductive material, wherein: the processor is disposed within the housing in thermal communication with the rear surface of the housing, and the housing has a depth sufficient to dispose the rear surface of the housing, when mounted on the surface, at a distance from a rear interior surface of the interior cavity sufficient to induce accelerated flow of air between the rear surface of the housing and the rear interior surface of the interior cavity when the processor generates heat.

### TECHNICAL FIELD

Various embodiments described herein relate to heat dissipation apparatuses, and more specifically, but not exclusively, heat dissipation apparatuses that are mounted in a confined space to enhance accelerated airflow for increased cooling capabilities.

### BACKGROUND

Many apparatuses are installed in walls or other fixtures in order to reduce the space the apparatuses occupy. Many of these apparatuses, such as televisions, Internet of Things (IoT) tablets, or household appliances have cooling components within the structure of the apparatus. These apparatuses generally do not have a significant cooling demand, but many apparatuses with high processing requirements, such as controller systems or computers, require larger cooling components, such as fans, additional heat sinks, etc. to cool the processor or other components because of the high thermal output of the apparatus. Typically, these devices do not have the passive cooling capability to cool their respective heat generating elements, as a significant amount of space would be required by fins or other heat sinks alone to adequately cool these devices. As such, installation of many high processing demand devices within walls or other surfaces is not common, as the space required to integrate these systems into walls is often too great.

### SUMMARY

According to various embodiments described herein, a heat dissipation apparatus is disclosed, including one or more of the following: A digital controller comprising: a processor; a memory; and a hollow housing configured to be mounted to a surface such that at least a portion of the housing is disposed within an interior cavity of the surface, wherein a rear surface of the housing is made of a heat-conductive material, wherein: the processor is disposed within the housing in thermal communication with the rear surface of the housing, and the housing has a depth sufficient to dispose the rear surface of the housing, when mounted on the surface, at a distance from a rear interior surface of the interior cavity sufficient to induce accelerated flow of air between the rear surface of the housing and the rear interior surface of the interior cavity when the processor generates heat.

Various embodiments additionally include a plurality of controller connectors disposed within an interior compartment of the hollow housing.

Various embodiments additionally include a display screen attached to the housing, wherein the display screen is moveable relative to the housing.

Various embodiments additionally include a mounting mechanism to mount the housing within an interior cavity of a surface, wherein, when the device is mounted, an anterior face of the housing is flush with an anterior face of the surface.

Various embodiments described herein relate to a heat dissipation apparatus, including one or more of the following: A device comprising: a heat generating element; and a housing configured to be mounted to a surface such that at least a portion of the housing is disposed within an interior cavity of the surface, wherein: the heat generating element is disposed within the housing in thermal communication with a heat dissipating element, and the housing has a depth sufficient to dispose the heat dissipating element at a distance from a rear interior surface of the interior cavity sufficient to induce accelerated flow of air between the heat dissipating element and the rear interior surface when the heat generating element generates heat.

Various embodiments are described wherein the heat dissipating element is the rear surface of the housing.

Various embodiments are described wherein the housing is hollow.

Various embodiments are described wherein the width of the housing is between 6 and 16 inches.

Various embodiments are described wherein a bottom edge of the rear surface is profiled in a manner sufficient to increase a flow rate of the accelerated flow.

Various embodiments additionally include a mounting mechanism to mount the housing within the interior cavity of the surface.

Various embodiments are described wherein the rear surface of the housing includes a heat conductive surface.

Various embodiments are described wherein the distance is around 1-3 cm.

Various embodiments are described wherein an anterior face of the housing is flush with an anterior face of the surface.

Various embodiments additionally include fins mounted on the back of the rear surface of the housing.

Various embodiments are described wherein the housing includes an interior compartment with electrical connections.

Various embodiments are described wherein the rear surface of the housing includes grooved channels for airflow.

Various embodiments are described wherein a method for mounting a device is disclosed, including: placing a device housing within a surface, wherein at least a portion of the housing is disposed within an interior cavity of the surface; and securing the device to the surface with a mounting mechanism such that the housing has a depth sufficient to dispose a rear surface of the housing at a distance from a rear interior surface of the interior cavity sufficient to induce accelerated flow of air between the rear surface of the housing and the rear interior surface of the surface when a heat generating element, disposed within the housing, generates heat.

Various embodiments are disclosed, wherein the housing is placed between 4 and 6 feet from ground level.

Various embodiments additionally include cutting an opening into the surface sufficient to place the device within the opening.

Various embodiments are disclosed, wherein the mounting mechanism includes components disposed within the device.

### BRIEF DESCRIPTION OF THE FIGURES

Non-limiting and non-exhaustive embodiments of the present embodiments are described with reference to the following drawings, wherein like reference numerals refer to like parts throughout the various views unless otherwise specified. In order to better understand various example embodiments, reference is made to the accompanying drawings, wherein:

FIG. 1A illustrates an example environment for which various embodiments disclosed herein may be implemented.

FIG. 1B illustrates an alternative example environment for which various embodiments disclosed herein may be implemented.

FIG. 1C illustrates a magnified view of a portion of the example environment of FIG. 1A or FIG. 1B.

FIG. 1D illustrates a top view of the example environment of FIG. 1A or FIG. 1B.

FIG. 2A illustrates an example device which may be mounted within the example environment in accordance with various embodiments.

FIG. 2B illustrates a second state of the example device of FIG. 2A.

FIG. 3A illustrates a side view diagram of an example embodiment of a controller, including a moveable display screen, in an example environment in accordance with various embodiments.

FIG. 3B illustrates a top view diagram of an example embodiment of a controller, including a moveable display screen, in an example environment in accordance with various embodiments.

FIG. 4A illustrates a side view diagram of an example embodiment of a controller, including a moveable display screen, and the stack effect associated therein, in accordance with various embodiments.

FIG. 4B illustrates a side view diagram of an example embodiment of a controller, including a moveable display screen, with a profiled bottom for more efficient airflow in accordance with various embodiments.

FIG. 4C illustrates a comparison of flow diagrams between various embodiments.

FIG. 5A illustrates atop view diagram of an side example embodiment of a controller, including a moveable display screen, with chimney wings fixed to the controller in accordance with various embodiments.

FIG. 5B illustrates a side view diagram of an example embodiment of a controller, including a moveable display screen, with chimney wings fixed to the controller in accordance with various embodiments.

FIG. 6 illustrates atop view diagram of an example embodiment of a controller, including a moveable display screen, possessing a chimney lattice in accordance with various embodiments.

### DETAILED DESCRIPTION

The description and drawings presented herein illustrate various principles. It will be appreciated that those skilled in the art will be able to devise various arrangements that, although not explicitly described or shown herein, embody these principles and are included within the scope of this disclosure. As used herein, the term, “or,” as used herein, refers to a non-exclusive or (i.e., and/or), unless otherwise indicated (e.g., “or else” or “or in the alternative”). Additionally, the various embodiments described herein are not necessarily mutually exclusive and may be combined to produce additional embodiments that incorporate the principles described herein.

The technical character of embodiments described herein will be apparent to one of ordinary skill in the art, and will also be apparent in several ways to a wide range of attentive readers. Some embodiments address concepts of fluid dynamics, such as inducing a stack effect to enhance the cooling capabilities of apparatuses. This may allow for less expenditures in cooling systems for apparatuses which generate excessive heat as a by-product of operation, as well as reducing the necessary space for the operation of high-demand processing apparatuses. Other advantages based on the technical characteristics of the teachings will also be apparent from the description provided.

As described in the background section, many high-demand processing apparatuses cannot be easily and sleekly confined into interior cavities due to the elevated cooling requirements associated with their thermal output. Various embodiments described herein present solutions to this issue, and the advantages of compartmentalization, heat dissipation, and more of the embodiments will be apparent.

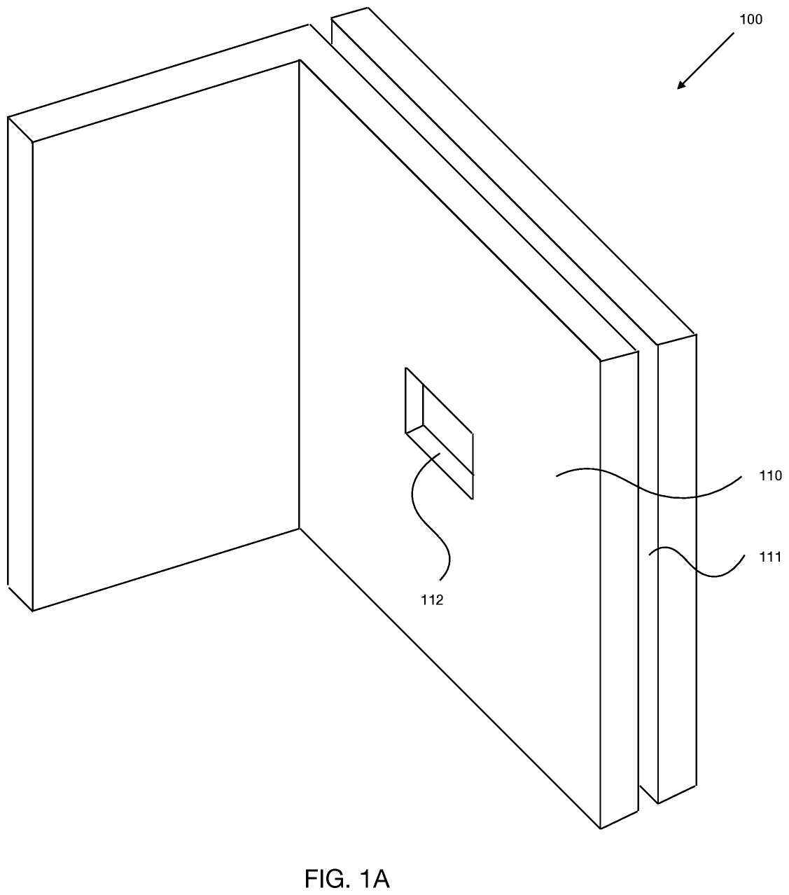

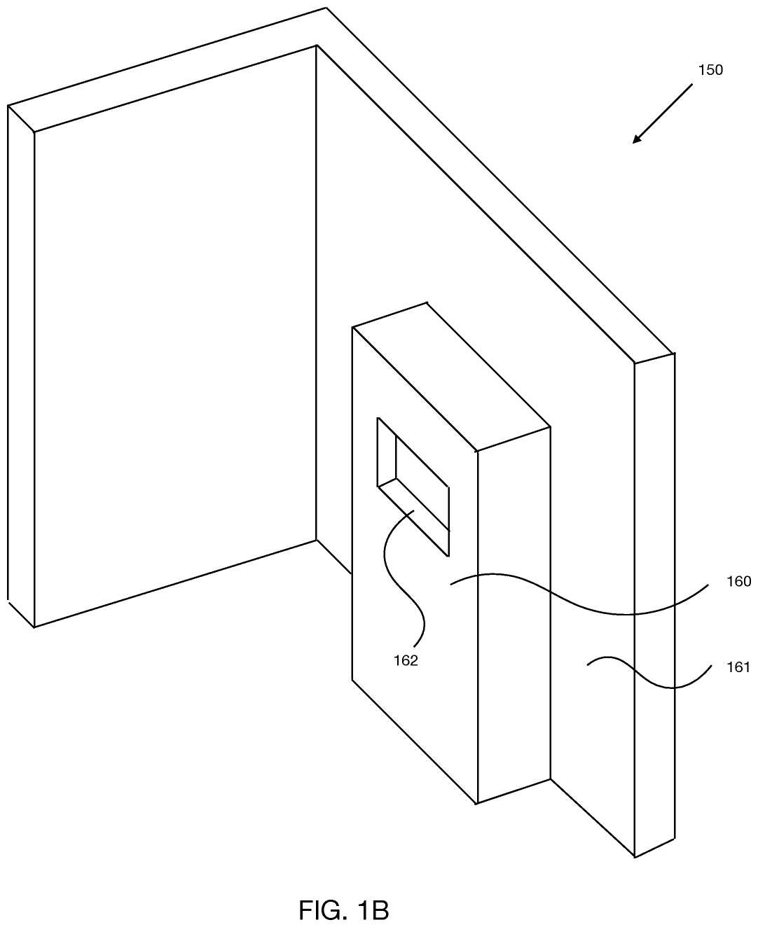

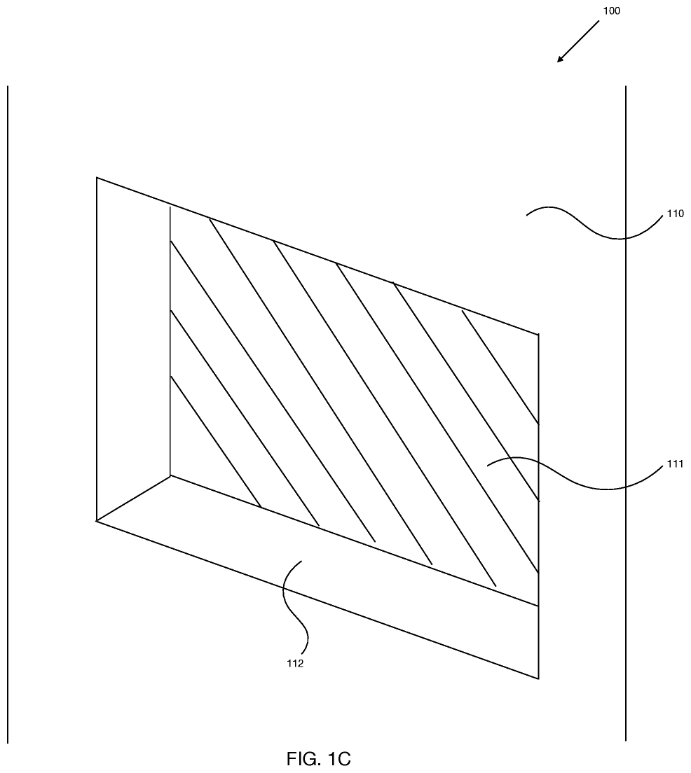

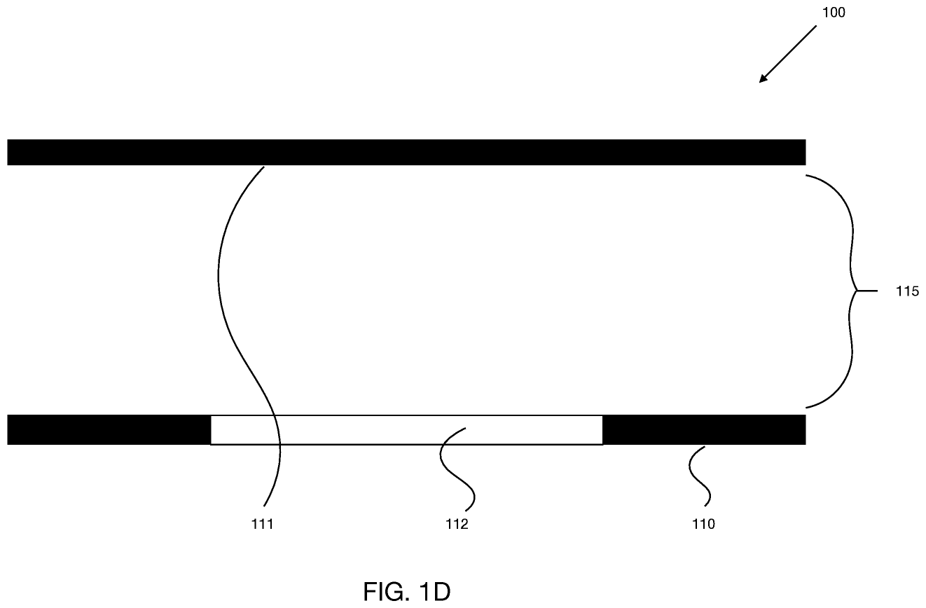

FIG. 1A illustrates an example environment 100 within which various embodiments disclosed herein may be implemented. An example environment 100 may be where a digital controller or other apparatus is implemented in accordance with various embodiments. A digital controller is used in this specification as an example, but various other electrical, or heat-generating, apparatuses could be installed in the environment 100 in place of the controller, including, but not limited to, televisions, computers, and hard drive towers. Virtually any system where enhanced cooling or compartmentalization is desired may benefit from the teachings herein. Various modifications to adapt the teachings and embodiments to fit a desired technology will be apparent. This example environment 100 illustrates a wall 110 in which a section has been removed, leaving a hole 112. The section removed from the wall 110 is illustrated as a rectangle, but various shapes, of various dimensions, may be implemented in accordance with various embodiments. The hole 112 may allow for access to an interior cavity 115 (shown in FIG. 1D) that may allow for placement of a device, such as a controller, within the interior cavity 115. The hole 112 does not cut through a rear interior surface 111, which may be a wall of another room, a load-bearing structure, or a medium between the wall 110 and another wall. Furthermore, the wall 110 is shown as a typical vertical wall within a space, but could be the face of a column, an angled or canted wall, or other surface which functions in the same role as a wall.

FIG. 1B illustrates an alternative example environment 150 within which various embodiments disclosed herein may be implemented. This alternative example environment 150 illustrates a surface 160, which may be an extension of a wall, such as a cabinet, additional framed wall, or other space with an interior cavity 115 (shown in FIG. 1C), in which a section of the surface 160 has been removed for mounting of a controller within the interior cavity 115 of the surface 160. The environment is depicted as located near a wall 161, but could be a free-standing space with an interior cavity 115. Similar to the example environment 100 of FIG. 1A, a hole 162 may cut through the surface 160, but not cut through a rear interior surface 161, which is depicted here as the wall 161, but could alternatively be the back of a cabinet or other back element of a wall or freestanding structure. For the purposes of describing the embodiments herein, the term “wall” will be used in reference to the object in which the hole 112 may be cut, but the term shall be construed to cover walls or surfaces as described in this paragraph.

FIG. 1C illustrates a magnified view of a portion of the example environment 100 of FIG. 1A, but may also describe the alternative example environment 150 of FIG. 1B. The removed section cuts through the entirety of a wall 110 exposed to the space, leaving an interior cavity 115 (depicted in FIG. 1D) of the surface accessible from the space. A rear interior surface 111 is not removed. The separation between the wall 110 and the rear interior surface 111 creates the interior cavity 115 that is accessible via hole 112. The depth of the interior cavity 115 (as shown in FIG. 1D) is an example environment depth, and the ratio of the depth of the interior cavity 115 to the wall 110 may vary.

FIG. 1D illustrates a top view of a portion of the example environment 100 of FIG. 1A, but may also describe the alternative example environment 150 of FIG. 1B. In this diagram, the wall 110, along with the rear interior surface 111 can be seen. Additionally, the space between the two surfaces, the interior cavity 115, is depicted. The interior cavity 115 may be the space between two drywall surfaces, a front and back of a cabinet, or any other two surfaces containing an interior cavity consistent with example environments 100, 150 in FIGS. 1A and 1B, as well as similar environments in which various embodiments may be implemented.

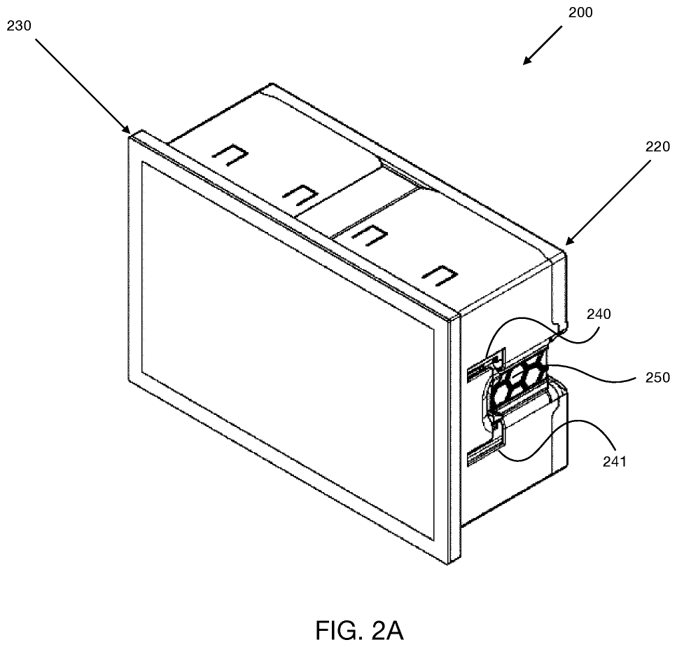

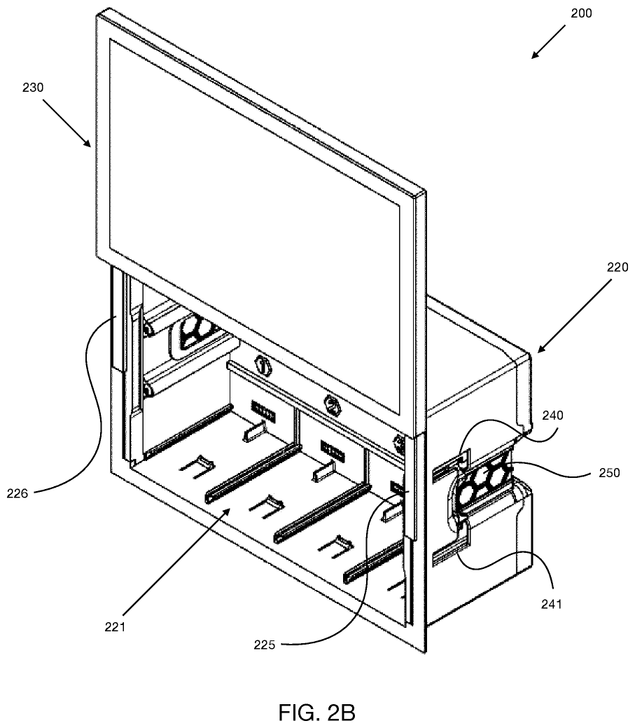

FIG. 2A illustrates an example device which may be mounted within the example environment 100 in accordance with various embodiments. A digital controller 200, which may be installed in the example environments 100, 150, may include a controller housing 220 and a display screen 230. The display screen 230 may be slidable relative to the controller housing 220, which may be hollow to allow for access to internal components, such as electrical connections to other apparatuses. The screen 230 may slide on a set of rails (not shown), but could also utilize any other mechanism suitable for allowing sliding movement. Furthermore, the screen 230 may be slidable or moveable in other directions, such as to the left or to the right of the controller housing 220 or movable in another, non-slidable manner (e.g. on a hinge, cord, magnetic system, or other mechanism). The controller housing 220 and screen 230 are merely example components, and these components may be any two different elements. Some examples include a memory compartment and a computer, or a power supply and a computer.

The controller housing 220 may have mounting mechanisms 240, 241, as well as additional mounting mechanisms (not shown). The controller may possess such a mechanism for mounting the controller 200 to a structure such as a wall 110 or other surface in example environments 100, 150. The mounting mechanisms 240, 241 are depicted as a system with a screw mechanism, controlling components comparable to toggle bolts, inside the controller housing 220, but other mechanisms, such as standard screws, adhesive strips or putty, or a support shelf inside a wall cavity or other surface with an interior cavity, may be used. In the illustrated embodiment, the mounting mechanisms 240, 241 may expand sideways so as to form a flat surface to attach to an interior surface of a wall. Such an arrangement (or various alternative arrangements) may enable the controller housing 220 to be installed at least partially within the wall, leaving the posterior face screen 230 flush with the anterior face of the wall or extending outward from the wall surface by only a short depth relative to the full depth of the interior cavity 115. The controller housing 220 may further comprise a wiring entry point 250, in which external wiring may enter into an interior portion of the controller housing. As shown in FIG. 2A, the screen 230 is currently in a closed position wherein the screen encloses an interior of the controller housing 220.

FIG. 2B illustrates a second state of the example device of FIG. 2A. As shown in FIG. 2B, the screen 230 is currently in an open position as the screen has slid upward compared to the first state, exposing the interior compartment 221 of the controller housing 220. The interior compartment 221 of the hollow housing may contain a plurality of controller connectors, which may be used to connect to field devices or other controllers. The controller may have sliding rails 225, 226, allowing for movement of the screen 230 vertically. As noted, other mechanisms besides rails may be used, including, but not limited to, hinges, cords, or detachable magnets.

In various embodiments, the controller 200 may be installed in a wall, such as the wall 110 depicted in environments 100, 150. The controller housing 220 may be installed in the wall 110 via mounting mechanisms 240, 241, and other mounting mechanisms (not shown), and the rear surface of the screen 230, and thus the anterior face of the controller housing 220, may be flush with the anterior face of the wall 110. The internal compartment 221 may thus be disposed, at least partially, in the interior cavity 115 of the wall 110. The compartment may allow for access to hardware for the screen 230 or other components. The screen 230 being slidable allows for access to the internal compartment 221 in such a setup. For example, a processor (such as a CPU or GPU) may reside in the controller housing 220, and a cable may be used to transmit information between the screen 230 and the processor. Other examples may include memory storage space in the internal compartment 221 for a computer, a power source for the screen 230, or components for a touchscreen interface for the screen 230. Using such a setup in the environments 100, 150 poses advantages with compartmentalization, and as will be discussed later, heat dissipation. The screen 230 may also be slidable for other purposes, such as being slidable for adjustments to height for user comfort. Various other advantages with be apparent.

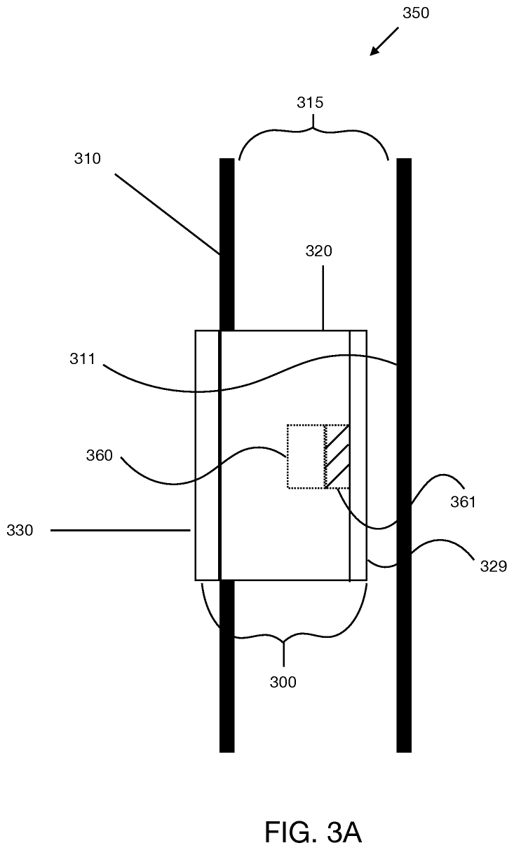

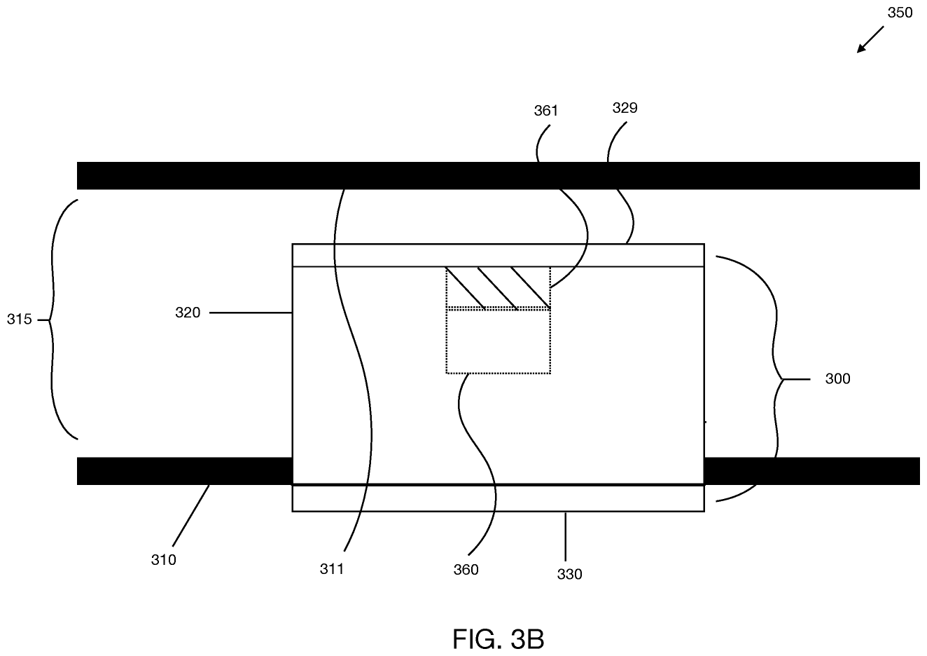

FIG. 3A illustrates a side view diagram of an example embodiment of a controller 300, including a moveable display screen 330, in an example environment 350 in accordance with various embodiments. Example environment 350 may correspond to example environments 100, 150 of FIGS. 1A and 1B. The controller 300 with the slidable display screen 330 is shown in the example environment 350. The controller 300 may be of a width between 6 inches and 16 inches, depending on the amount of electrical connections necessary as well as the cooling requirements of the controller 300. A controller housing 320 is disposed within an interior cavity 315, such that a heat dissipating element 329 of the controller housing 320 is in close proximity to a rear interior surface 311 of the interior cavity 315. The heat dissipating element 329 may be the rear surface of the housing, components, such as fins, attached to the rear surface, or any other components suitable for heat dissipation. The controller housing 320 may be connected to the screen 330, which may be flush with a wall 310. A heat generating element 360 may be disposed within the controller housing 320, and in thermal communication with the heat dissipating element 329 via a thermal medium 361. The heat generating element 360 may be a processor, memory, or other component. The thermal medium 361 may include a paste; heat-conductive connection, such as metal; or other known mechanisms for thermally connecting two components. Alternatively, the heat generating element 360 may directly connect to the heat dissipating element 329. FIG. 3B illustrates an top view diagram of this example embodiment.

The example controller 300 in FIGS. 3A and 3B may possess mounting mechanisms similar to the controller 200 of FIGS. 2A and 2B. The controller 300 may also be mounted by other means to the wall 310 or the rear interior surface 311. FIGS. 3A and 3B are not fit to scale, and the proportion of the controller within the interior cavity 315 may be different from that depicted. Furthermore, the location of the heat generating element 360 is merely an example, and any location along the heat dissipating element 329, along with any corresponding location of the thermal medium 361, within the housing 320 is possible. Various embodiments may posses multiple heat generating elements 360, along with multiple thermal mediums 361.

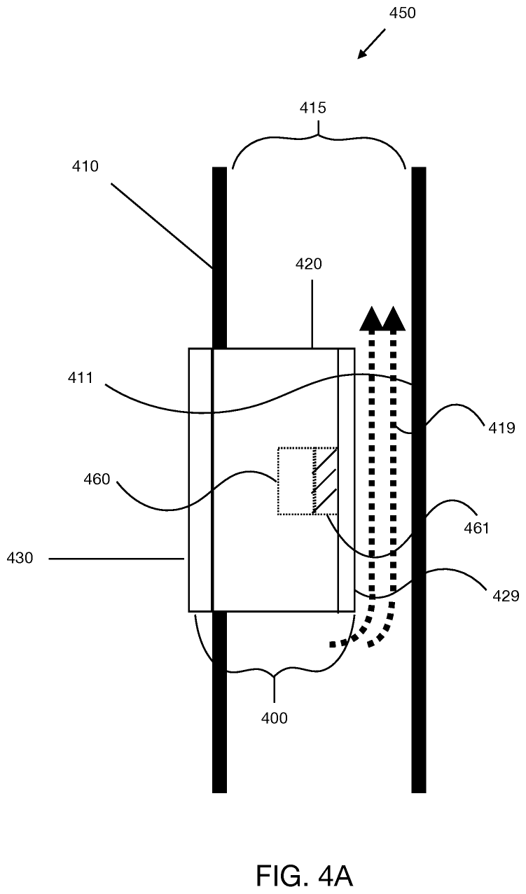

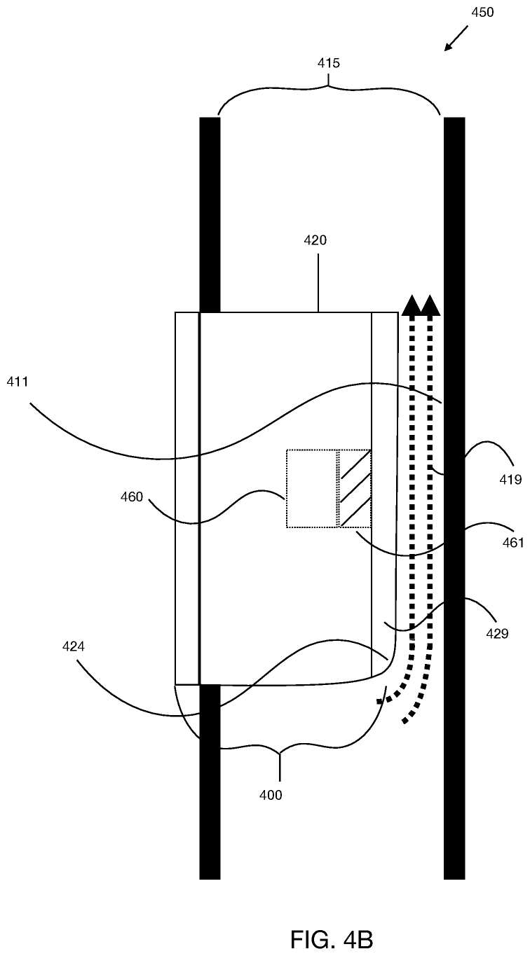

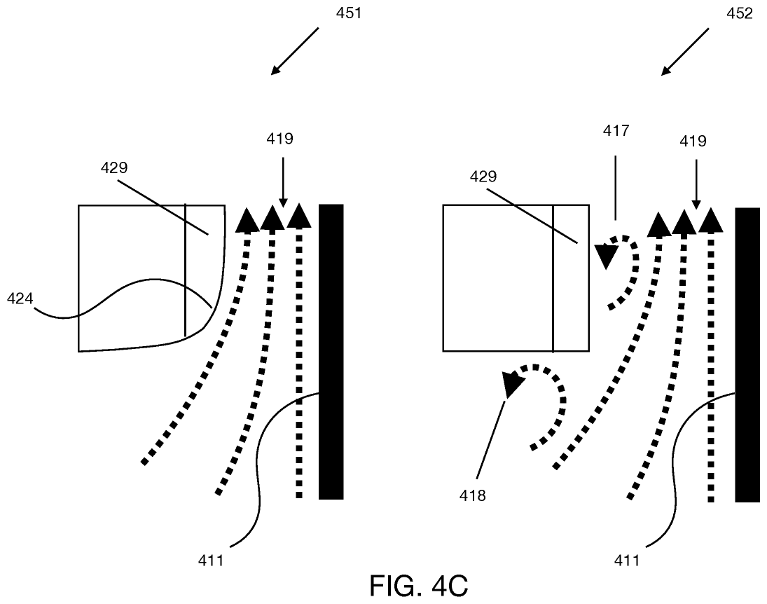

FIG. 4A illustrates a side view diagram of an example embodiment of a controller 400, including a moveable display screen 430, installed in a wall 410 in environment 450 and the stack effect associated therein, in accordance with various embodiments. The controller 400 may correspond to the controllers 200, 300 of FIGS. 2 and 3. The wall 410 may correspond to the wall 110 of FIG. 1A, the surface 160 of FIG. 1B, or the wall 310 of FIGS. 3A and 3B. A fluid dynamic effect, the stack effect, is caused by the disposition of the controller 400 in an interior cavity 415 with a heat dissipating element 429 within a controller housing 420 of the controller 400 in close proximity to a rear interior surface 411 of the interior cavity 415. The proximity may vary, but close proximities, specifically those around one to three centimeters, were found to be the most effective. The appropriate distance will vary depending on the size of the apparatus, the total heat generation, and other factors. When a heat generating element 460 generates heat, heat may transferred from the heat generating element 460 to the heat dissipating element 429. In some embodiments, heat may be transferred from the heat generating element 460 to a thermal medium 461, which then may transfer heat to the heat dissipating element 429. The heat dissipating element may be formed, in part or entirety, from heat-conductive material, such as a metal with a high thermal conductivity value, or plastic. The heat dissipating element 429, being at an elevated temperature relative to the temperature of the air within the interior cavity 415, transfers thermal energy to the air within the interior cavity 415 that is in contact with the heat dissipating element 429, causing the air to rise in temperature. The close proximity of the heat dissipating element 429 and the rear interior surface 411 provides a narrow channel which air may occupy between the two surfaces, 429, 411. The small channel for the air in the interior cavity 415 causes an accelerated airflow 419. As the air in the interior cavity 415 is heated, the air rises, developing a stack effect due to the narrow channel in which the air may move upward between the heat dissipating element 429 and the rear interior surface 411. The accelerated airflow provides for faster cooling of the heat dissipating element 429, as cooler air is “pulled up” when the heated air rises, and, in turn, thermal energy is removed from the heat dissipating element 429 into the air. The heat dissipating element 429 may then pull additional thermal energy from the heat generating element 460, thereby cooling the heat generating element 460. Various embodiments may, include additional features to amplify or otherwise facilitate this effect, such as grooved channels of rectangular, semicircle, or other suitable shapes, on the heat dissipating element 429 of the controller 400, or fins, comprising heat conductive material, attached to the heat dissipating element 429. It will be apparent that grooved channels or fins may increase the surface area of the heat dissipating element 429, thus increasing the rate of heat transfer between the air within the interior cavity 415 and the heat dissipating element 429.

FIG. 4B illustrates a side view diagram of an example embodiment of a controller 400, including a moveable display screen 430, with a profiled bottom 424 for more efficient airflow installed in a wall 410 in environment 450 in accordance with various embodiments. The controller 400 may again correspond to the controllers 200, 300 of FIGS. 2 and 3. The wall 410 may correspond to the wall 110 of FIG. 1A, the surface 160 of FIG. 1B, or the wall 310 of FIGS. 3A and 3B. In various embodiments, the controller housing 420 may possess a profiled bottom 424, which is depicted as a rounded bottom in the figure, but may be an angled bottom at a more gradual angle than 90 degrees, a combination of a rounded and angled bottom, or other suitable contouring. The profiled bottom may provide two separate effects: a partial funneling effect and a reduction in turbulent flow. As the width of the channel between the heat dissipating element 429 and the rear interior surface 411 starts wider with the presence of the profiled bottom 424, and then tapers to be more narrow near the center of the controller 400, the velocity of the air increase from the profiled bottom 424 towards the top of the controller 400. In turn, the faster airflow provides for more heat transfer between the air within the interior cavity 415 and the heat dissipating element 429. The profiled bottom 424 also provides with a smoother transition of the air in the interior cavity 415 towards the channel between the heat dissipating element 429 and the rear interior surface 411. In turn, the presence of turbulent flow, as well as recirculating eddies surrounding the bottom edge of the controller 400, are reduced, thereby increasing the rate of accelerated airflow 419.

FIG. 4C illustrates a comparison of flow diagrams of the profiled bottom 424 versus a 90 degree angled bottom of the controller housing 420. As shown, eddies 417, 418 are generated in response to the abrupt transition from the width of interior cavity 415 to the channel between the heat dissipating element 429 and the rear interior surface 411, whereas a gradual transition is present in embodiments with the profiled bottom 424. These diagrams are not comprehensive analyses, and eddies may be present in embodiments with the profiled bottom 424. However, the degree of eddies and turbulent flow in such embodiments may be less than that of a 90 degree angled bottom. Furthermore, the profiled bottom 424 is illustrated as a shallow curve, but may be of various dimensions and curvatures, both of which will influence the degree of increase of accelerated flow in comparison to a 90 degree angled bottom embodiment.

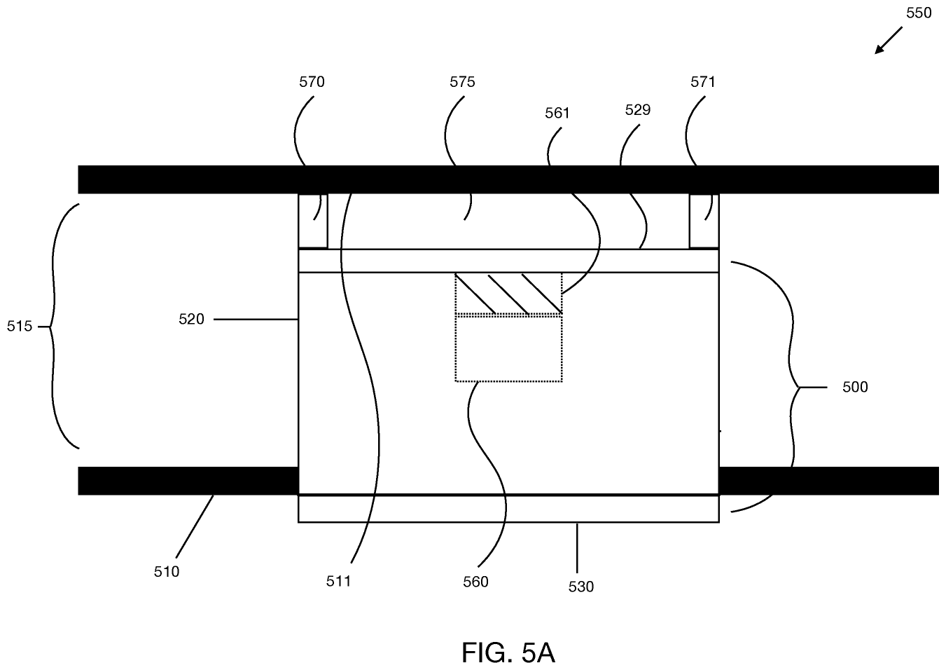

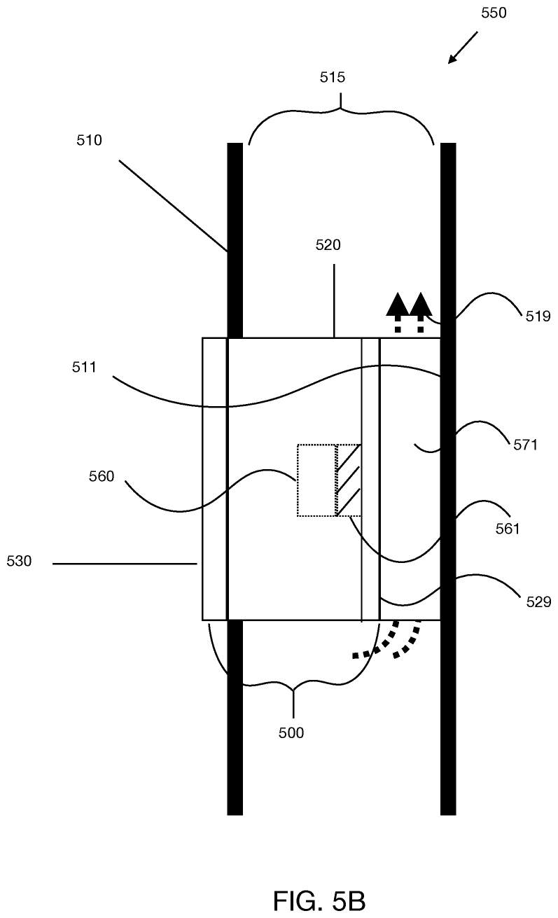

FIG. 5A illustrates a top view diagram of an example embodiment of a controller 500, including a moveable display screen 530, with chimney wings 570, 571 fixed to a heat dissipating element 529, installed in a wall 510 in an environment 550 in accordance with various embodiments. The controller 500 and the environment 550 may correspond to previous controllers and environments described herein. In various embodiments, chimney wings 570, 571 may be attached to the heat dissipating element 529. The chimney wings 570, 571 may also attach to a controller housing 520 for structural support. The chimney wings 570, 571 are depicted as being the length of the height of the controller 500, but may be shorter, longer, or of a different shape, such as following the contour of the profiled bottom 424 in FIG. 4B. The chimney wings serve to further isolate the air within the interior cavity 515, and create a fuller chimney channel 575 between the heat dissipating element 529, the chimney wings 570, 571, and the rear interior surface 511. The chimney wings 570, 571 may be formed of metal, or another heat conductive material, and thus the chimney wings 570, 571 may further heat the air within the chimney channel 575. FIG. 5B illustrates a side view diagram of this example embodiment. The accelerated airflow 519 would be further accelerated by a larger surface area of heat transfer in embodiments with chimney wings 570, 571, formed from heat-conductive material. Furthermore, the chimney wings 570, 571 prevent the air within the interior cavity 515 from exiting on ether side of heat dissipating element 529 of the controller housing 520. The chimney wings 570, 571 may thereby force the air to travel vertically, producing a stronger stack effect with fewer losses to the left or right of the controller 500 in FIG. 5A. In turn, the heat transfer of the system is augmented and the cooling of the heat generating element 560 is enhanced. The heat generating element 560 may be attached to the heat dissipating element 529 via a thermal medium 561. The chimney wings 570, 571 may also serve as, or as part of, a mounting mechanism of the controller.

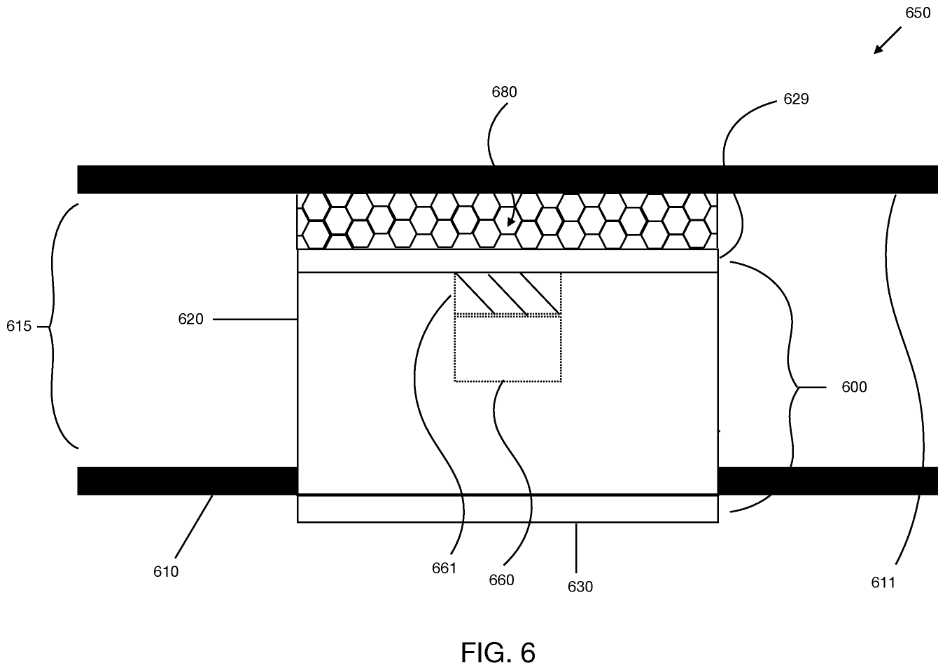

FIG. 6 illustrates a top view diagram of an example embodiment of a controller 600, including a moveable display screen 630, possessing a chimney lattice 680, installed in a wall 610 in environment 650 in accordance with various embodiments. The controller 600 and the environment 650 may correspond to previous controllers and environments described herein. In various embodiments, the chimney channel 575 of FIG. 5A may be filled with a chimney lattice 680. The chimney lattice 680 is depicted as hexagon channels, but any suitable shape, and any suitable size for said shape given the distance between the heat dissipating element 629 and the rear interior surface 611, may be used. The chimney lattice may be formed of metal, or another heat conductive material, and thus the chimney lattice 680 may further heat the air within each lattice opening. In this manner, the isolation of air within the interior cavity 615 into even smaller channels than the chimney channel of FIG. 5A increases the heat transfer rate of each lattice opening, and provides for a smaller volume of air to heat, which in turn causes a more accelerated airflow for each lattice opening. In turn, the heat transfer of the heat dissipating element 629, and thus of the heat generating element 660, is further enhanced. The heat generating element 660 may be connected to the heat dissipating element 629 through a thermal medium 661. The chimney lattice 680 may also serve as, or as part of, a mounting mechanism of the controller, and may be attached to the controller housing 620 as part of the mounting mechanism or for structural support.

It should be apparent from the foregoing description that various example embodiments of the invention may be implemented in hardware. Although the various exemplary embodiments have been described in detail with particular reference to certain example aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the scope of the claims.

1. A digital controller comprising:
a processor;
a memory; and
a hollow housing configured to be mounted to a surface such that at least a portion of the housing is disposed within an interior cavity of the surface, wherein a rear surface of the housing is made of a heat-conductive material,
wherein:
the processor is disposed within the housing in thermal communication with the rear surface of the housing, and
the housing has a depth sufficient to dispose the rear surface of the housing, when mounted on the surface, at a distance from a rear interior surface of the interior cavity sufficient to induce accelerated flow of air between the rear surface of the housing and the rear interior surface of the interior cavity when the processor generates heat.

2. The device of claim 1, further comprising a plurality of controller connectors disposed within an interior compartment of the hollow housing.

3. The device of claim 1, further comprising a display screen attached to the housing, wherein the display screen is moveable relative to the housing.

4. The device of claim 1, further comprising a mounting mechanism to mount the housing within an interior cavity of a surface, wherein, when the device is mounted, an anterior face of the housing is flush with an anterior face of the surface.

5. A device comprising:
a heat generating element; and
a housing configured to be mounted to a surface such that at least a portion of the housing is disposed within an interior cavity of the surface,
wherein:
the heat generating element is disposed within the housing in thermal communication with a heat dissipating element, and
the housing has a depth sufficient to dispose the heat dissipating element at a distance from a rear interior surface of the interior cavity sufficient to induce accelerated flow of air between the heat dissipating element and the rear interior surface when the heat generating element generates heat.

6. The device of claim 5, wherein the heat dissipating element is the rear surface of the housing.

7. The device of claim 5, wherein the housing is hollow.

8. The device of claim 5, wherein the width of the housing is between 6 and 16 inches.

9. The device of claim 5, wherein a bottom edge of the rear surface is profiled in a manner sufficient to increase a flow rate of the accelerated flow.

10. The device of claim 5, further comprising a mounting mechanism to mount the housing within the interior cavity of the surface.

11. The device of claim 5, wherein the rear surface of the housing comprises a heat conductive surface.

12. The device of claim 5 wherein the distance is around 1-3 cm.

13. The device of claim 5, wherein an anterior face of the housing is flush with an anterior face of the surface.

14. The device of claim 5, further comprising fins mounted on the back of the rear surface of the housing.

15. The device of claim 5, wherein the housing comprises an interior compartment with electrical connections.

16. The device of claim 5, wherein the rear surface of the housing comprises grooved channels for airflow.

17. A method for mounting a device comprising:
placing a device housing within a surface, wherein at least a portion of the housing is disposed within an interior cavity of the surface; and
securing the device to the surface with a mounting mechanism such that the housing has a depth sufficient to dispose a rear surface of the housing at a distance from a rear interior surface of the interior cavity sufficient to induce accelerated flow of air between the rear surface of the housing and the rear interior surface of the interior cavity when a heat generating element, disposed within the housing, generates heat.

18. The method of claim 17, wherein the housing is placed between 4 and 6 feet from ground level.

19. The method of claim 17, further comprising cutting an opening into the surface sufficient to place the device within the opening.

20. The method of claim 17, wherein the mounting mechanism comprises components disposed within the device.
